(19) United States
(12) Patent Application Publication
(10) Pub. No.: US 2003/0214017 A1
(43) Pub. Date: Nov. 20, 2003

(54) Method of manufacturing a semiconductor device

(75) Inventors: Naoki Yokoi, Hyogo (JP); Hiroshi Tanaka, Hyogo (JP); Masahiko Higashi, Hyogo (JP); Yasuhiro Asaoka, Hyogo (JP); Toshihiko Nagai, Hyogo (JP)

Correspondence Address: McDERMOTT, WILL & EMERY, 600 13th Street, N.W., Washington, DC, 20005-3096, US

(73) Assignees: Mitsubishi Denki Kabushiki Kaisha; Matsushita Electric Industrial Co., Ltd

(21) Appl. No.: 10/283,261

(22) Filed: Oct. 30, 2002

(30) Foreign Application Priority Data
May 17, 2002 (JP) 2002-143310(P)

(51) Int. Cl. H01L 23/58

(52) U.S. Cl. 257/648

(57) ABSTRACT

A gate electrode including a polycrystalline silicon film and a sidewall insulating film are formed on a semiconductor substrate with a gate insulating film therebetween. The semiconductor substrate provided with the gate electrode is brought into contact with a predetermined plating solution to deposit a cobalt film on the semiconductor substrate by electroless plating. Then, a heat treatment is effect to cause a reaction between the silicon in the gate electrode and the cobalt as well as a reaction between the silicon in the semiconductor substrate and the cobalt to form a cobalt silicide film. Thereafter, the unreacted cobalt film is removed. Thereby, damage to the semiconductor substrate can be suppressed, and salicide process can be simplified.

### BACKGROUND OF THE INVENTION

1. Field of the Invention

The present invention relates to a method of manufacturing a semiconductor device and a film forming apparatus used for the same, and particularly to a semiconductor device manufacturing method in which a metal film is formed.

2. Description of the Background Art

Processes of manufacturing semiconductor devices have primarily employed film forming or depositing methods such as a sputtering method, in which vapor growth is executed with plasma, for forming metal films on silicon wafers. A salicide process applied to a cobalt film will now be described as an example employed in a conventional method of manufacturing a semiconductor device.

First, as shown in FIG. 27, a gate electrode 105 made of, e.g., a polycrystalline silicon film is formed on a semiconductor substrate 101 with a gate insulating film 103 therebetween. Sidewall insulating films 107 are formed on the opposite side surfaces of gate electrode 105, respectively.

Then, sputter-etching is effected to clean a surface of semiconductor substrate 101. Then, as shown in FIG. 28, sputtering is executed to form a cobalt film 109 over gate electrode 105 and sidewall insulating films 107.

Then, as shown in FIG. 29, heat treatment is performed in a predetermined atmosphere at a predetermined temperature so that reactions occurs between silicon in gate electrode 105 and cobalt and between silicon in semiconductor substrate 101 and cobalt, and cobalt silicide films 111 are formed. Then, an unreacted cobalt film is removed. In the conventional salicide process, cobalt silicide films 111 are formed as described above.

In the conventional salicide process, however, sputter-etching is effected on the surface of semiconductor substrate 101 for cleaning the surface of semiconductor substrate 101 before forming cobalt film 109, as already described. Therefore, plasma damages the surface of semiconductor substrate 101.

For preventing oxidization of cobalt film 109 formed on the surface of semiconductor substrate 101, a cap layer (not shown) of titanium nitride or the like may be formed on the surface of semiconductor substrate 101. If formed, a step of removing this cap layer is additionally required after the heat treatment.

### SUMMARY OF THE INVENTION

The invention has been developed for overcoming the above disadvantages, and an object of the invention is to provide a semiconductor device manufacturing method, which can reduce damage to a semiconductor substrate, and can achieve a salicide process more easily. Another object of the invention is to provide a film forming apparatus, which can be applied to the semiconductor device manufacturing method.

A semiconductor device manufacturing method for forming a conductive film on a semiconductor substrate according to an aspect of the invention includes a film forming step of forming the conductive film containing predetermined metal on the semiconductor substrate by bringing a liquid containing the predetermined metal or a compound of the predetermined metal in a dissolved state into contact with the semiconductor substrate to deposit the predetermined metal.

According to this manufacturing method, since the conductive film is formed by bringing the semiconductor substrate into contact with the liquid to deposit the predetermined metal, the surface of the semiconductor substrate is prevented from being damaged by plasma in contrast to a conventional method, in which a conductive film is produced from a vapor phase by sputtering or the like.

It is preferable that the method includes a heat treatment step of effecting a heat treatment to form a silicide film of the predetermined metal by causing a reaction between the predetermined metal in the conductive film and silicon after the film forming step, and the heat treatment step is performed immediately after completion of the film forming step.

Thereby, it is not necessary to employ a cap layer, which is formed on the surface of the conductive film for preventing oxidization of the conductive film in a conventional manufacturing method. Consequently, formation and removal of an additional film such as a cap layer are not required, and the film forming process can be simplified.

More specifically, the conductive film is preferably formed by electroless plating.

In this case, the predetermined metal can be deposited on the surface of the semiconductor substrate by chemical substitution between different kinds of metal and/or reduction reaction so that the conductive film can be formed easily.

A film forming apparatus for forming a conductive film on a semiconductor substrate according to another aspect of the invention includes a first processing portion for forming the conductive film containing predetermined metal on the semiconductor substrate by bringing a liquid containing the predetermined metal or a compound of the predetermined metal in a dissolved state into contact with the semiconductor substrate to deposit the predetermined metal.

According to this structure, since the conductive film is formed by bringing the semiconductor substrate into contact with the liquid to deposit the predetermined metal, the surface of the semiconductor substrate is prevented from being damaged by plasma in contrast to a conventional method, in which a conductive film is produced from a vapor phase by sputtering or the like.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a step in a semiconductor device manufacturing method according to a first embodiment of the invention;

FIGS. 2, 3 and 4 show steps according to the first embodiment, and particularly the steps performed after the steps shown in FIGS. 1, 2 and 3, respectively;

FIG. 5 shows a step in a semiconductor device manufacturing method according to a second embodiment of the invention;

FIGS. 6 and 7 show steps according to the second embodiment, and particularly the steps performed after the steps shown in FIGS. 5 and 6, respectively;

FIG. 8 shows a structure of a film forming apparatus according to a third embodiment of the invention;

FIG. 9 shows a first example of a processing tank employed in the film forming apparatus of the third embodiment shown in FIG. 8;

FIG. 10 shows a method of manufacturing the semiconductor device by the film forming apparatus of the third embodiment shown in FIG. 8;

FIGS. 11 to 19 show second to tenth examples of the processing tank employed in the film forming apparatus of the third embodiment shown in FIG. 8, respectively;

FIG. 20 shows an operation of the processing tank of the tenth example of the third embodiment shown in FIG. 19;

FIG. 21 shows an eleventh example of the processing tank employed in the film forming apparatus of the third embodiment shown in FIG. 8;

FIG. 22 shows an operation of the processing tank of the eleventh example of the third embodiment shown in FIG. 21;

FIG. 23 shows a structure of a film forming apparatus according to a fourth embodiment of the invention as well as a first state in an operation of the same;

FIGS. 24, 25 and 26 shows second, third and fourth states in the operation of the film forming apparatus according to the fourth embodiment, respectively;

FIG. 27 is a cross section showing a step in a conventional semiconductor device manufacturing method;

FIG. 28 is a cross section showing a step performed after the step shown in FIG. 27; and

FIG. 29 is a cross section showing a step performed after the step shown in FIG. 28.

### DESCRIPTION OF THE PREFERRED EMBODIMENTS

First Embodiment

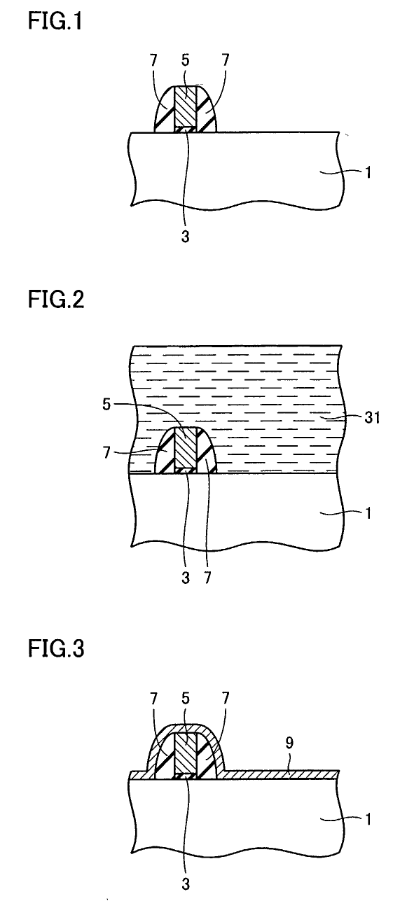

As a semiconductor device manufacturing method according to a first embodiment of the invention, an example of a salicide process will now be described. First, as shown in FIG. 1, a gate electrode 5 including a polycrystalline silicon film is formed on a semiconductor substrate 1 with a gate insulating film 3 therebetween. Then, sidewall insulating films 7 are formed on the opposite side surfaces of gate electrode 5, respectively.

Then, as shown in FIG. 2, semiconductor substrate (wafer) 1 provided with gate electrode 5 is brought into contact with a predetermined plating solution 31, and a cobalt film 9 is deposited on semiconductor substrate 1 by electroless plating, as shown in FIG. 3.

The electroless plating is generally a method, in which a metal coating is deposited on a surface of a solid body by chemical substitution between different kinds of metal and/or reduction reaction. In the above case, plating solution 31 contains, as major ingredients, salt of cobalt and a reducing agent. The reducing agent reduces the salt of cobalt so that cobalt is deposited on the surface of semiconductor substrate (wafer) 1, i.e., plating target or work, and will grow into a film.

The salt of cobalt may be cobalt chloride, cobalt sulfate or the like. The reducing agent may be sodium hypophosphite or the like. In addition to these major ingredients, the plating solution may contain a pH adjuster, buffer agent, complexing agent and others.

The pH adjuster may be salt of ammonium hydroxide or the like, inorganic acid, organic acid or the like. The buffer agent is employed for suppressing variations in pH-value, which may occur in accordance with progression of plating, and may be formed of sodium citrate, boric acid or the like. The complexing agent is used for suppressing settling of metal, and is formed of ammonium hydroxide, sodium citrate, sodium tartrate or the like depending on the pH-value of the plating solution.

A minute amount of sulfide or fluoride may be added to the plating solution for increasing a metal deposition efficiency. A pH-value of the electroless plating solution of cobalt is kept in a range from about 7 to about 10.

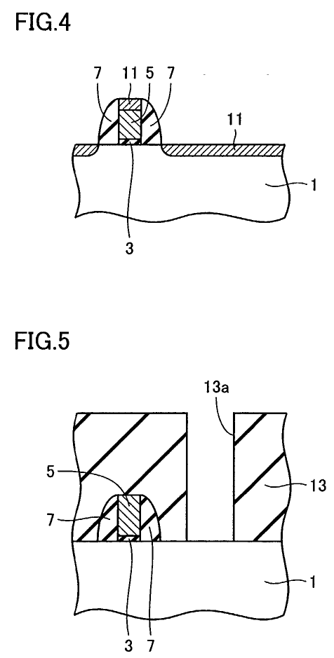

Then, as shown in FIG. 4, predetermined heat treatment is performed to cause a reaction between silicon in gate electrode 5 and cobalt as well as a reaction between silicon in semiconductor substrate 1 and cobalt so that a cobalt silicide film 11 is formed.

The above heat treatment is preferably performed under such conditions that semiconductor substrate 1 is placed in a vacuum or an atmosphere of an inert gas such as a nitrogen gas, and is kept at a temperature ranging from 200 to 500° C. for a time from about 30 seconds to about 5 minutes.

Thereafter, an unreacted cobalt film is removed. In this processing, it is preferable to use hydrochloric acid, sulfuric acid or the like as acid for removing hydrofluoric acid. Instead of the above acid, a mixture solution, e.g., of the above acid and a hydrogen peroxide solution may be used. The solution temperature is preferably in a range from a room temperature to 130° C. In this manner, cobalt silicide film 11 is formed on silicon wafer 2.

In the manufacturing method described above, semiconductor substrate 1 is brought into contact with plating solution 31 so that cobalt film 9 is formed by electroless plating. Thereby, such a situation is prevented that the surface of semiconductor substrate 1 is damaged before formation of cobalt film 9, in contrast to a conventional salicide process.

The cobalt film has been described as an example of the metal film in the first embodiment. However, a film of another kind of metal allowing electroless plating may be deposited. For example, a nickel film may be deposited with plating solution containing, as a major ingredient of metal salt, nickel chloride, nickel sulfate, nickel hypophosphite or the like.

By effecting the predetermined heat treatment already described, a nickel silicide film can be formed. In this case, the electroless plating solution of the nickel preferably has a pH-value in a range from about 4 to about 11.

The method described above is not restricted to a salicide process, and may be employed for depositing a mere metal film such as a cobalt film, nickel film or the like.

Second Embodiment

As a semiconductor device manufacturing method according to a second embodiment of the invention, description will now be given on another example of the salicide process. After the same step as that in the first embodiment shown in FIG. 1, a CVD method or the like is executed to form a silicon oxide film 13 covering gate electrode 5 and sidewall insulating films 7 on semiconductor substrate 1, as shown in FIG. 5.

A predetermined resist pattern (not shown) is formed over silicon oxide film 13. Anisotropic etching is effected on silicon oxide film 13 masked with the above resist pattern to form a contact hole 13a exposing the surface of semiconductor substrate 1.

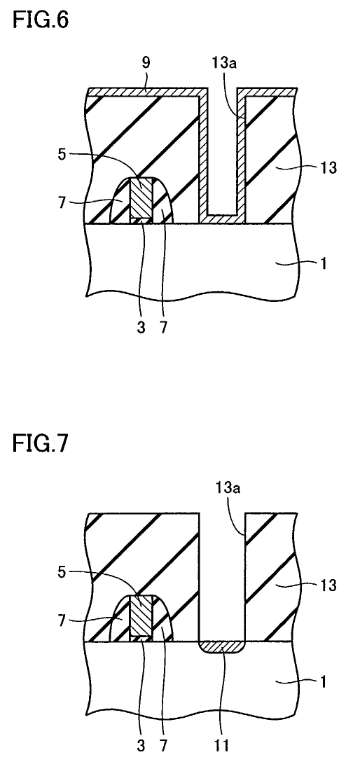

Similarly to the step in the first embodiment shown in FIG. 2, semiconductor substrate (wafer) 1 provided with contact hole 13a is brought into contact with the predetermined plating solution so that the electroless plating is executed to deposit cobalt film 9 on silicon oxide film 13 and in contact hole 13a, as shown in FIG. 6.

Similarly to the step in the first embodiment shown in FIG. 4, the predetermined heat treatment is performed to cause a reaction between cobalt and silicon in semiconductor substrate 1 exposed on the bottom of contact hole 13a so that cobalt silicide film 11 is formed as shown in FIG. 7. Thereafter, unreacted cobalt film 9 is removed as already described in connection with the first embodiment.

Then, a plug (not shown) is formed in contact hole 13a so that an interconnection (not shown) formed, e.g., on silicon oxide film 13 is electrically connected to a predetermined region of the semiconductor substrate.

In a conventional manufacturing method, the cobalt film is formed by a vapor growth method such as a sputtering method. In the vapor growth method, it is difficult to form the cobalt film on the surface of semiconductor substrate 1 exposed on the bottom of contact hole 13a. Therefore, a cobalt silicide film cannot be formed on the bottom of contact hole 13a in an intended fashion.

According to the manufacturing method described above, semiconductor substrate 1 comes into contact with predetermined plating solution 31 in the step shown in FIG. 6, whereby the electroless plating is executed to form cobalt film 9 on silicon oxide film 13 and in contact hole 13a.

In this case, the plating solution can easily enter contact hole 13a so that good cobalt film 9 can be formed in contact hole 13a and on the bottom of contact hole 13a, in contrast to the case of forming the cobalt film by the vapor growth. As a result, cobalt silicide film 11 can be on the bottom of contact hole 13a in a preferred fashion.

According to the embodiment described above, the cobalt film has been described as an example of the metal film. As already described in connection with the first embodiment, however, a nickel film or the like may be deposited as a film of another kind of metal allowing the electroless plating. Further, a nickel silicide film may be formed by performing a predetermined heat treatment.

The method described above is not restricted to the salicide process, and may be employed for depositing a mere metal film such as a cobalt film, nickel film or the like.

Third Embodiment

A semiconductor device manufacturing method according to a third embodiment of the invention will now be described in connection with a more specific method of forming a metal film by the electroless plating as well as an example of a film forming apparatus used for the same.

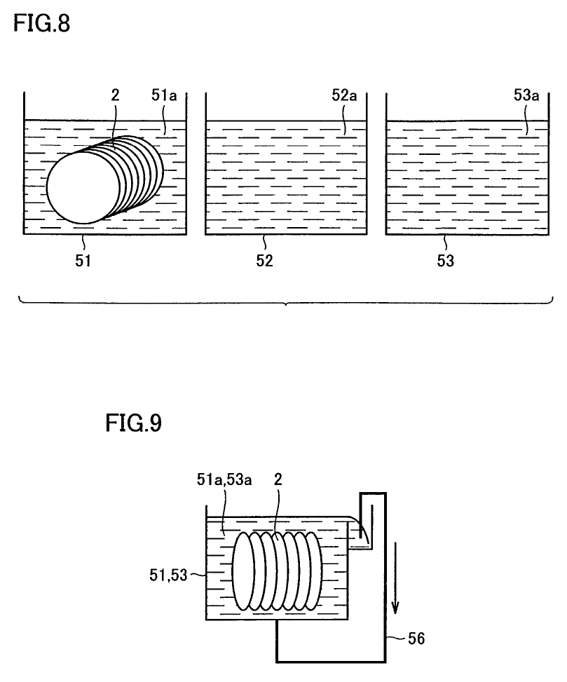

First, as shown in FIG. 8, a film forming apparatus for forming a metal film includes a processing tank 51 for storing a chemical cleaning solution 51a, a processing tank 52 for storing water 52a and a processing tank 53 for storing a predetermined plating solution 53a.

FIG. 9 shows a processing tank of a circulating type as a specific example of processing tanks 51 and 53. Processing tanks 51 and 53 in FIG. 9 are configured to circulate chemical cleaning solution 51a or plating solution 53a stored in processing tank 51 or 53 via a pipe 56.

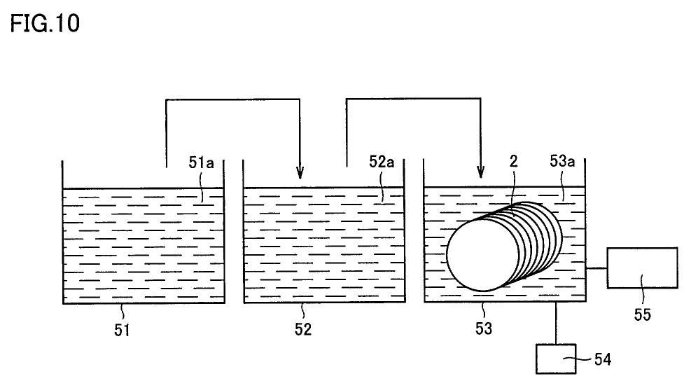

In this film forming apparatus, as shown in FIG. 10, silicon wafer (semiconductor substrate) 2, on which a metal film of cobalt or the like is to be formed, is immersed in chemical cleaning solution 51a of, e.g., HF stored in processing tank 51. Then, silicon wafer 2 is removed from processing tank 51, and is immersed in water 52a stored in processing tank 52a for rinsing silicon wafer 2. Thereafter, silicon wafer 2 is removed from processing tank 52.

Then, silicon wafer 2 is brought into contact with predetermined plating solution 53a stored in processing tank 53. As already described in connection with the first and second embodiments, the electroless plating is performed by bringing silicon wafer 2 into contact with predetermined plating solution 53a so that a cobalt film is deposited on silicon wafer 2 (plating processing). In this manner, the cobalt film is formed as the metal film on silicon wafer 2.

In the method of forming the metal film described above, steps of and between cleaning of silicon wafer 2 and formation of the cobalt film can be executed only by one film forming apparatus so that the process of forming the cobalt film can be further simplified.

Since the one film forming apparatus continuously performs a series of processing of and between cleaning of silicon wafer 2 and formation of the cobalt film, such a situation can be avoided that silicon wafer 2 is contaminated by an atmosphere or the like.

In the film forming apparatus described above, processing tank 53 storing plating solution 53a is made of, e.g., stainless steel. In this case, when plating solution 53a deteriorates due to use, the plating may be effected on processing tank 53 itself. Accordingly, an appropriate positive voltage may be applied to processing tank 53 for preventing processing tank 53 itself from being plated.

Further, as shown in FIG. 10, the apparatus may includes a plating solution analyzing portion 55, which samples a part of plating solution 53a in processing tank 53 by a pump or the like, and analyzes the composition of sampled plating solution 53a, and a plating solution refilling portion 54 for refilling the ingredients of plating solution into processing tank 53 based on results of the analysis.

In this case, variations in ingredients of the plating solution can be suppressed to ensure the stability in the plating. Plating solution analyzing portion 55 can appropriately perform the analysis by measuring an ion concentration by a colorimeter, measuring pH by a glass electrode or the like.

In the example of the film forming apparatus described above, processing tank 51 storing chemical cleaning solution 51a is arranged independently of processing tank 52 storing water 52a, and the cleaning and the rinsing are performed in the different processing tanks, respectively. However, a processing tank of a one-bath type may be employed to perform the cleaning and rinsing in the same processing tank.

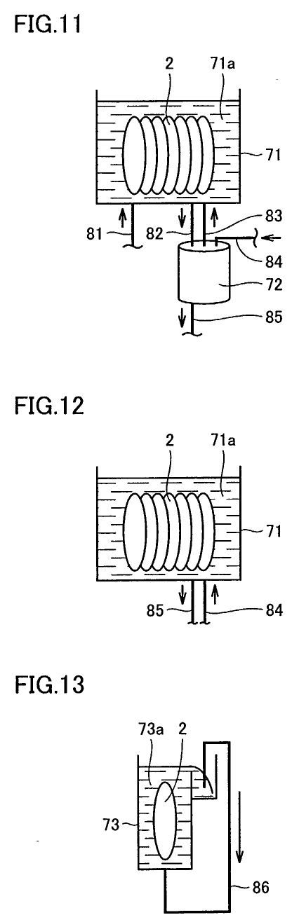

An example of the one-bath type of processing tank will now be described. As shown in FIG. 11, a processing tank 71 is employed, and pipes 84 and 83 for supplying the chemical cleaning solution via a tank 72 as well as a pipe 81 for supplying pure water are connected to processing tank 71. A pipe 82 for collecting the chemical cleaning solution or water 71a, which is stored in processing tank 71, into tank 72 is also connected to processing tank 71. Further, a pipe 85 is connected to tank 72 for discharging the collected chemical cleaning solution or water.

Processing tank 71 operates as follows. First, equipment (not shown) inside or outside the film forming apparatus supplies the chemical cleaning solution into tank 72 via pipe 84, and the chemical cleaning solution thus stored in tank 72 is supplied via pipe 83 to processing tank 71. After wafer 2 is cleaned with the chemical cleaning solution, the chemical cleaning solution is temporarily collected in tank 72 via pipe 82.

Thereafter, water is supplied into processing tank 71 via pipe 81, and wafer 2 is rinsed. Thereafter, the water is collected in tank 72 via pipe 82, and is discharged via pipe 85 as a liquid waste.

The chemical cleaning solution collected in tank 72 will be supplied for reuse to processing tank 71 via pipe 83 in the next cleaning step. The chemical cleaning solution, which has deteriorated due to the reuse, is discharged as a liquid waste via pipe 85.

Another example of the processing tank of the one-bath type will be described. As shown in FIG. 12, processing tank 71 is connected to pipe 84 for supplying the chemical cleaning solution and the water as well as pipe 85 for discharging the chemical cleaning solution or water 71a stored in processing tank 71.

Processing tank 71 in FIG. 12 is first supplied with the chemical cleaning solution via pipe 84 from appropriate equipment (not shown) inside or outside the film forming apparatus. After wafer 2 is cleaned with chemical cleaning solution, the chemical cleaning solution is discharged as a liquid waste via pipe 85.

Then, water is supplied via pipe 84 into processing tank 71, and wafer 2 is rinsed. Then, the water is discharged as a liquid waste via pipe 85. In this manner, the cleaning and rinsing of wafer 2 are performed in one processing tank 71. Processing tank 71 described above is of the one-bath batch type.

According to the examples of the film forming apparatus already described, each of the cleaning and rinsing of the silicon wafer is performed one time before bringing the silicon wafer into contact with the plating solution. However, each of the cleaning and rinsing may be performed two or more times. A drying tank may be arranged for drying the silicon wafer after the cleaning and rinsing of the silicon wafer and before the immersion in the plating solution.

A rinsing tank may be employed for rinsing silicon wafer 2 after the plating of silicon wafer 2 in processing tank 53, and also a drying tank may be employed for drying silicon wafer 2 thus rinsed.

In the foregoing cases, the processing tank of the one-bath type may be used so that the plating of silicon wafer 2 and the rinsing of plated silicon wafer 2 may be performed in the same processing tank. In particular, it is preferable that processing tank 71 provided with tank 72 shown in FIG. 11 is employed as the processing tank of the one-bath type for reusing the plating solution.

The film forming apparatus has been described in connection with an example of the batch type, in which the plurality of silicon wafers are processed at a time. However, a sheet-feeding or successive processing type, in which silicon wafers are processed one by one, may be employed. In the case of the successive processing type, appropriate manners are employed for bringing the silicon wafer into contact with the chemical cleaning solution, water and others, similarly to the batch type.

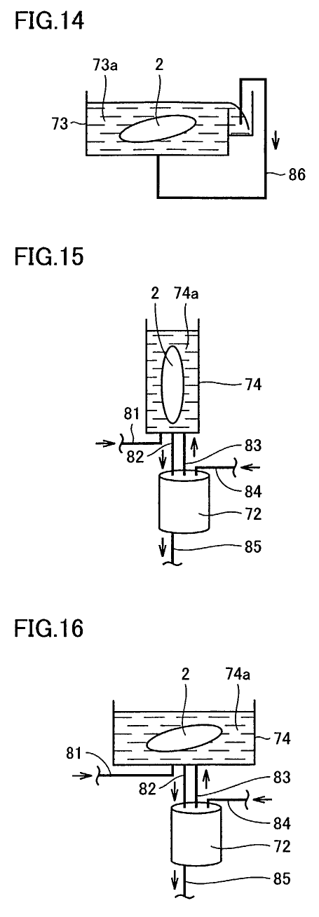

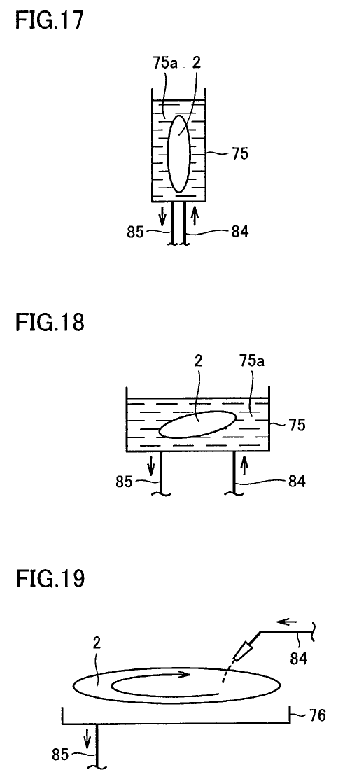

In this case, the processing tank of the circulating type may be formed of a processing tank 73 shown in FIGS. 13 and 14, and the processing tank of the one-bath type may be formed of a processing tank 74 or 75 shown in FIGS. 15-18. Pipes and others connected to or provided for these processing tanks 73, 74 and 75 basically have the same structures as those for the processing tank of the batch type. Therefore, the same members bear the same reference numbers, and description thereof is not repeated.

Particularly, as shown in FIGS. 14, 16 and 18, silicon wafer 2 may be arranged substantially horizontal in the process of the successive processing type, or may be slightly inclined with respect to the substantially horizontal position. The front surface of silicon wafer 2 may be directed upward or downward. Further, silicon wafer 2 may be rotated.

The processing tank for applying the plating solution to silicon wafer 2 may be preferably formed of processing tank 74, which allows reuse of the plating solution as shown in FIGS. 15 and 16. In the successive processing type, the chemical cleaning solution, water or the like may be supplied to the silicon wafer, which is being rotated or spun. In this case, a processing tank 76 of a spin type shown in FIGS. 19-22 may be used.

According to the structure employing processing tank 76 shown in FIG. 19, pipe 84 is arranged above processing tank 76 for supplying the chemical cleaning solution, water or the like to the surface of silicon wafer 2 from a nozzle of pipe 84. A pipe 85 for discharging a liquid waste is connected to processing tank 76.

According to processing tank 76, chemical cleaning solution or the like is applied from the nozzle of pipe 84 to the surface of silicon wafer 2, which is being rotated.

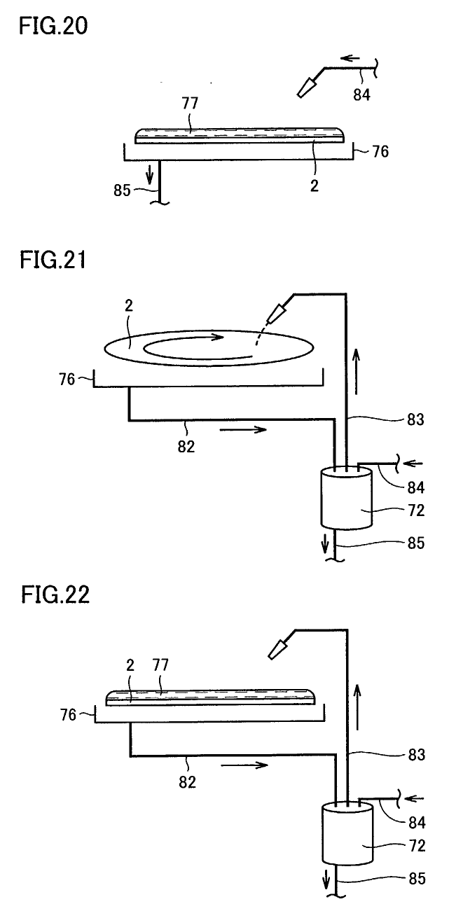

As shown in FIG. 20, once the chemical cleaning solution 77 or the like is supplied to the whole surface of silicon wafer 2, supply of the chemical cleaning solution or the like and rotation of silicon wafer 2 are stopped, and this state will be kept for a predetermined period. During this period, predetermined processing is effected on silicon wafer 2.

Thereafter, silicon wafer 2 is rotated again, and water or the like is supplied for rinsing the surface of silicon wafer 2.

Processing tank 76 shown in FIGS. 21 and 22 employs pipes and others, of which structures are basically the same as those of the processing tank (see FIG. 11) of the batch type provided with the additional tank. Operations of performing the predetermined processing by applying the cleaning solution and others from the nozzle pipe are substantially the same as those of the processing tank already described.

In particular, when the plating solution is used, processing tank 76 will be able to collect and reuse the plating solution after the use. Therefore, processing tank 76 can be preferably used as the processing tank for applying the plating solution to silicon wafer 2.

If the plating is performed by the processing tank of the successive processing type, it is preferable that the plating is effected on only the front surface of the silicon wafer by holding the silicon wafer while sealing its rear surface.

In the plating process with processing tank 76 shown in FIGS. 19 to 22, the plating solution is applied to the surface of silicon wafer 2 from the nozzle of pipe 84, and pure water is applied to the rear surface of silicon wafer 2 from a nozzle of another pipe. Thereby, the plating can be effected only on the front surface of silicon wafer 2.

Fourth Embodiment

Description will now be given on an example of the film forming apparatus according to the fourth embodiment of the invention as well as a method of forming a metal film by this example of the apparatus performing the electroless plating.

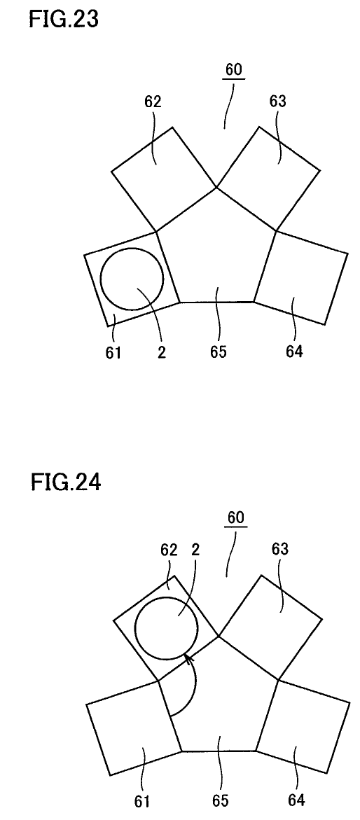

First, as shown in FIG. 23, a film forming apparatus 60 for forming a metal film includes a first chamber 61 for cleaning a silicon wafer with HF or the like, a second chamber 62 for forming the metal film with a predetermined plating solution, a third chamber 63 for heating silicon wafer 2 and a fourth chamber 64 for removing unreacted metal with an etching liquid.

First to fourth chambers 61-64 are mutually connected via a load lock chamber 65.

An example of the processing (operation) by film forming apparatus 60 will now be described. First, as shown in FIG. 23, silicon wafer 2 to be coated with a metal film of cobalt or the like is cleaned with a chemical cleaning solution in first chamber 61.

The cleaning is performed by immersing silicon wafer 2 in the chemical cleaning solution (not shown) stored in first chamber 61, or applying the chemical cleaning solution to silicon wafer 2 from a nozzle pipe (not shown) arranged in first chamber 61. First chamber 61 preferably has a function of rinsing silicon wafer 2 after cleaning with the chemical cleaning solution.

Then, as shown in FIG. 24, silicon wafer 2 is moved into second chamber 62 via load lock chamber 65. In second chamber 62, silicon wafer 2 is brought into contact with the plating solution so that the metal film of cobalt is formed by the electroless plating. Thereafter, rinsing and drying may be effected on silicon wafer 2 in second chamber 62.

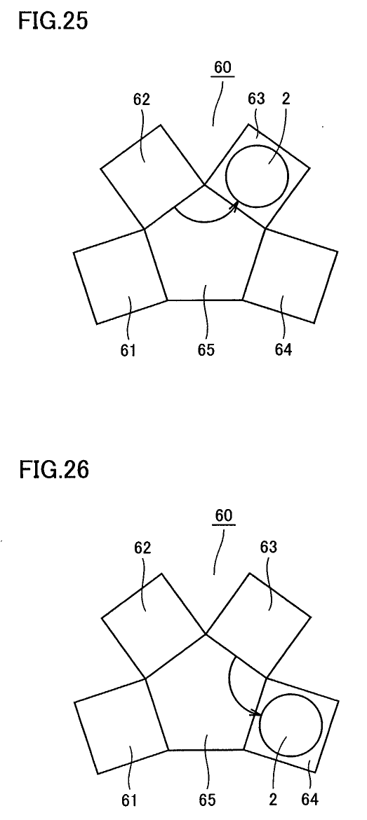

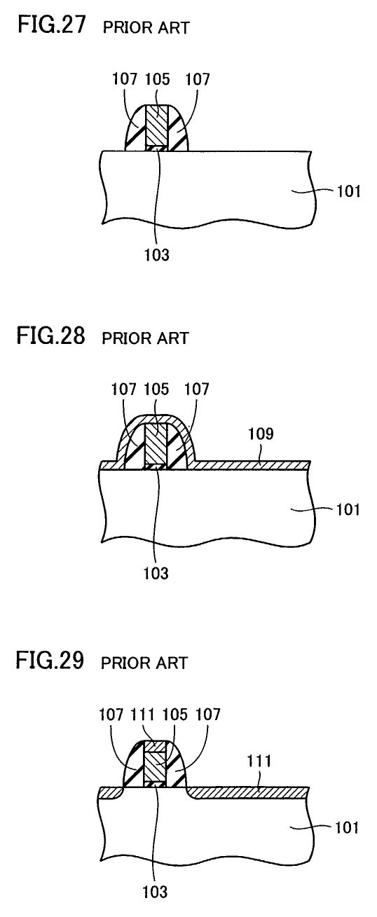

As shown in FIG. 25, silicon wafer 2 is moved into third chamber 63 via load lock chamber 65, and predetermined heat treatment is effected on silicon wafer 2 so that the silicon reacts with the cobalt to form a cobalt silicide film.

Then, as shown in FIG. 26, silicon wafer 2 is moved into fourth chamber 64 via load lock chamber 65, and the etching liquid of acid or the like is brought into contact with silicon wafer 2 to remove the unreacted cobalt film in fourth chamber 64. Thereafter, the rinsing and drying are effected on silicon wafer 2. In this manner, a cobalt silicide film is formed on silicon wafer 2.

According to the process of forming the metal film by film forming apparatus 60 described above, a series of processing of and between rinsing of silicon wafer 2 and formation of the cobalt film is continuously performed by the one film forming apparatus while moving silicon wafer 2 via load lock chamber 65. Thereby, it is possible to prevent contamination of silicon wafer 2 with a surrounding atmosphere, air or the like.

According to film forming apparatus 60 described above, the cobalt silicide film is formed by performing the predetermined heat treatment in third chamber 63 immediately after formation of the cobalt film in second chamber 62.

Therefore, film forming apparatus 60 described above can form the cobalt silicide film without requiring a cap layer such as a titanium nitride film, which is formed on a surface of the cobalt film for preventing oxidization of the cobalt film in a conventional manufacturing method. Consequently, formation and removal of an additional film such as a cap layer are not required so that the film forming steps can be further simplified.

The processing tank arranged within first chamber 61 may be formed of the processing tank of the successive processing type shown in FIG. 13 or 14, if the processing tank is of the circulating type. If the processing tank is of the one-bath type, the processing tanks of the successive processing type shown in FIGS. 15-18 may be selectively employed. If the processing tank is of the spin type, the processing tank of the successive processing type shown in FIGS. 19-22 may be employed.

In particular, when consideration is given to the convenience in transfer of the silicon wafer in film forming apparatus 60 as well as to the fact that the drying is performed in first chamber 61 in addition to the rinsing, the processing tank arranged in first chamber 61 is preferably formed of the processing tank of the successive processing type shown in FIGS. 19-22. The processing tank of the successive processing type shown in FIGS. 19-22 may be provided with nozzle pipes for ejecting the chemical cleaning solution and pure water toward the front and rear surfaces of the silicon wafer, if necessary.

When consideration is given to the reuse of the plating solution and the convenience in transfer of silicon wafer 2, the processing tank arranged in second chamber 62 is preferably selected from processing tanks 73, 74 and 76 of the successive processing type shown in FIGS. 14, 16, 21 and 22.

In particular, processing tank 76 of the successive processing type shown in FIGS. 21 and 22 allows the rinsing and drying in the same processing tank 76. The plating solution may be applied to the front surface of silicon wafer 2 from the nozzle of pipe 84, and at the same time, pure water may be ejected to the rear surface of silicon wafer 2 from a nozzle pipe (not shown). Thereby, only the front surface of silicon wafer 2 can be plated.

Since processing tank 74 shown in FIG. 16 is of the one-bath type, the rinsing can be performed in the same processing tank 74. Further, the drying can be performed by rotating silicon wafer 2 pulled up from the water.

In processing tank 73 shown in FIG. 14, silicon wafer 2 is temporarily pulled up to a higher position in processing tank 73, and the pure water may be ejected to silicon wafer 2 from a nozzle pipe (not shown) arranged in the higher position within processing tank 73 so that the rinsing of silicon wafer 2 can be performed in the same processing tank 2. Further, the drying may be performed by rotating silicon wafer 2, which is pulled up from the plating solution or pure water to a higher position.

According to processing tanks 73 and 74 shown in FIGS. 13 and 16, silicon wafer 2 can be held while keeping the rear surface thereof in a sealed state. Thereby, the plating can be effected only on the front surface of silicon wafer 2.

Similarly to the third embodiment already described, second chamber 62 is preferably provided with a plating solution analyzing portion for analyzing the ingredients of the sampled plating solution and a plating solution refilling portion for refilling the ingredients of plating solution into second processing tank 62 based on results of the analysis.

The processing tank arranged in fourth chamber 64 is preferably formed of a processing tank similar to that arranged in first chamber 61 already described.

Film forming apparatus 60 described above includes first to fourth chambers 61 to 64, which are provided, e.g., for the respective steps in the film forming process, and are independent of each other. However, the specific processing tanks, which are arranged in the various chambers as described above, may be configured such that different kinds of operations or treatments are performed in a single processing tank and, for example, the rinsing in first chamber 61 and the heat treatment in third chamber 63 are replaced with the rinsing and heat treatment performed in the single processing tank. This can significantly reduce sizes of the film forming apparatus.

In the embodiments already described, the electroless plating is used for forming the metal film. In addition to this, such processing may be employed that a semiconductor substrate (silicon wafer) is brought into contact with alkaline aqueous solution containing ions of predetermined metal or its compound to form an extremely thin film of the metal or compound thereof on the semiconductor substrate.

In this case, it is likewise possible to prevent the surface of the semiconductor substrate from being damaged by plasma before formation of the metal film. By effecting the predetermined heat treatment after the metal film is formed, the silicide film of the metal can be formed.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device manufacturing method for forming a conductive film on a semiconductor substrate, comprising:
a film forming step of forming said conductive film containing predetermined metal on said semiconductor substrate by bringing a liquid containing the predetermined metal or a compound of said predetermined metal in a dissolved state into contact with said semiconductor substrate to deposit said predetermined metal.

2. The semiconductor device manufacturing method according to claim 1, further comprising:
a cleaning step of cleaning said semiconductor substrate before said film forming step, wherein
said film forming step is executed immediately after completion of said cleaning step.

3. The semiconductor device manufacturing method according to claim 2, further comprising:
a heat treatment step of effecting a heat treatment to form a silicide film of said predetermined metal by causing a reaction between said predetermined metal in said conductive film and silicon after said film forming step, wherein
said heat treatment step is performed immediately after completion of said film forming step.

4. The semiconductor device manufacturing method according to claim 3, further comprising:
a step of leaving said silicide film of said predetermined metal by removing the unreacted conductive film after said heat treatment step.

5. The semiconductor device manufacturing method according to claim 4, wherein
said conductive film is formed by electroless plating in said film forming step.

6. The semiconductor device manufacturing method according to claim 3, wherein
said conductive film is formed by electroless plating in said film forming step.

7. The semiconductor device manufacturing method according to claim 2, wherein
said conductive film is formed by electroless plating in said film forming step.

8. The semiconductor device manufacturing method according to claim 1, further comprising:
a heat treatment step of effecting a heat treatment to form a silicide film of said predetermined metal by causing a reaction between said predetermined metal in said conductive film and silicon after said film forming step, wherein
said heat treatment step is performed immediately after completion of said film forming step.

9. The semiconductor device manufacturing method according to claim 8, further comprising:
a step of leaving said silicide film of said predetermined metal by removing the unreacted conductive film after said heat treatment step.

10. The semiconductor device manufacturing method according to claim 9, wherein
said conductive film is formed by electroless plating in said film forming step.

11. The semiconductor device manufacturing method according to claim 8, wherein
said conductive film is formed by electroless plating in said film forming step.

12. The semiconductor device manufacturing method according to claim 1, wherein
said conductive film is formed by electroless plating in said film forming step.

13. The semiconductor device manufacturing method according to claim 1, wherein
a cobalt film or a nickel film is formed as said conductive film in said film forming step.
